(19) United States
(12) Patent Application Publication
(10) Pub. No.: US 2008/0211101 A1
(43) Pub. Date: Sep. 4, 2008

(54) Interlayer wiring of semiconductor device using carbon nanotube and method of manufacturing the same

(76) Inventors: In-Taek Han, Yongin-si (KR); Ha-Jin Kim, Yongin-si (KR)

Correspondence Address: Robert E. Bushnell, Suite 300, 1522 K Street, N.W., Washington, DC, 20005, US

(21) Appl. No.: 11/785,588

(22) Filed: Apr. 18, 2007

(30) Foreign Application Priority Data
Jul. 4, 2006 (KR) 10-2006-0062412

(51) Int. Cl. H01L 23/48; H01L 21/44

(52) U.S. Cl. 257/752; 438/597; 257/E23.01

(57) ABSTRACT

Provided is an interlayer wiring structure of a semiconductor device using carbon nanotubes, and a method of manufacturing the interlayer wiring structure. The interlayer wiring structure is a carbon nanotube bundle that connects a first electrode to a second electrode. The carbon nanotube bundle includes a plurality of carbon nanotubes grown from a catalyst layer that is formed on a first electrode. The carbon nanotube bundle is made in a manner that a portion of the carbon nanotube bundle close to the second electrode has higher density of carbon nanotubes than another portion of the carbon nanotube bundle close to the first electrode. The carbon nanotube bundle is surrounded by an interlayer dielectric. In one embodiment of a method of manufacturing the carbon nanotube interlayer wire, liquid droplets are distributed between the carbon nanotubes to induce surface tension between the carbon nanotubes. The surface tension makes the carbon nanotube bundle maintain higher density of carbon nanotubes in a portion close to the second electrode.

### CLAIM OF PRIORITY

This application makes reference to, incorporates the same herein, and claims all benefits accruing under 35 U.S.C. §119 from an application for INTERLAYER WIRING OF SEMICONDUCTOR DEVICE USING CARBON NANOTUBE AND MANUFACTURING PROCESS OF THE SAME earlier filed in the Korean Intellectual Property Office on the 4 of Jul. 2006 and there duly assigned Serial No. 10-2006-0062412.

### BACKGROUND OF THE INVENTION

1. Field of the Invention

The present invention relates to an interlayer wiring of a semiconductor device and a method of manufacturing the same, and more particularly, to an interlayer wiring of a semiconductor device that uses carbon nanotubes to reduce electrical resistance and to increase current density, and to a method of manufacturing the interlayer wiring, which includes a process of forming a plurality of highly densified carbon nanotubes.

2. Description of the Related Art

Semiconductor devices, in particularly semiconductor memories, include various memory devices such as a dynamic RAM (DRAM), a static RAM (SRAM), a phase change RAM (PRAM), and a magnetic RAM (MRAM). The memory devices generally include a metal oxide semiconductor (MOS) transistor as a switching device. The memory device includes wires, which work as an electron migration path, such as a contact and an interconnect. As the integration density of semiconductor devices increases, the width of the wires is relatively reduced while the amount of current passing the wire increases. Therefore, current density, which is defined as an amount of current per cross sectional area, increases. It is expected that the current density in a wire of semiconductor devices will be dramatically increased in the near future. For example, the current density in a wire of semiconductor devices is expected to reach approximately 10⁶ A/cm² by the year of 2010.

Metal wires made of aluminum or copper are mainly used in the contemporary semiconductor devices. However, there is limitations for increasing the current density in the metal wires while reducing line width of the metal wires, even though the reduction of line width and the increase of current density are essential for the highly integrated semiconductor devices. Therefore, it is expected that the degree of the integration of semiconductor devices that use metal wires may reach limits in the near future due to the reasons described above.

Accordingly, effort to replace the metal wires with carbon nanotube wires, which can maintain higher current density in a given line width than metal wires, is recently being conducted in order to overcome the limits caused by metal wires in highly integrated semiconductor devices. Although the wires of semiconductor devices can be replaced with carbon nanotubes, increasing density of the carbon nanotubes, however, is an issue, because the contemporary trend of the development of semiconductor devices would require more highly integrated semiconductor devices, and would require wires that could maintain higher current density without causing trouble.

### SUMMARY OF THE INVENTION

The present invention provides an interlayer wiring structure of a semiconductor device that can reduce electrical resistance and can increase current density, and a method of manufacturing the interlayer wiring structure.

The present invention also provides an interlayer wiring structure of a semiconductor device that can be applied to a minute via hole through which an extremely high integration density of the semiconductor device can be achieved, and a method of manufacturing the interlayer wiring structure.

According to an aspect of the present invention, there is provided an interlayer wiring structure of a semiconductor device comprising a first electrode, a catalyst layer that is electrically connected to the first electrode and grows carbon nanotubes, a second electrode spaced apart from the catalyst layer, a carbon nanotube bundle formed between the catalyst layer and the second electrode, and an interlayer dielectric surrounding the carbon nanotube bundle. The carbon nanotube bundle includes a plurality of carbon nanotubes that are grown from the catalyst layer. A portion of the carbon nanotube bundle close to the second electrode has higher density of carbon nanotubes than another portion of the carbon nanotube bundle close to the first electrode.

According to another aspect of the present invention, there is provided a method of manufacturing an interlayer wire of a semiconductor device. The method comprising steps of preparing a first electrode, forming a catalyst layer that grows carbon nanotubes and is electrically connected to the first electrode, growing a plurality of carbon nanotubes from the catalyst layer, forming a carbon nanotube bundle that includes the plurality of carbon nanotubes, forming an interlayer dielectric that surrounds the carbon nanotube bundle while a distant end of the carbon nanotube bundle distant to the first electrode is exposed out of the interlayer dielectric, and forming a second electrode connected to the carbon nanotube bundle. A portion of the carbon nanotube bundle close to the second electrode has higher density of carbon nanotubes than another portion of the carbon nanotube bundle close to the first electrode.

The step of forming of the carbon nanotube bundle can include steps of distributing droplets between the plurality of carbon nanotubes and evaporating the droplets. In this case, the droplets can be distributed by soaking the carbon nanotubes in a liquid or by spraying the carbon nanotubes with a liquid. The droplets can have surface tension greater than restoring elastic force of the carbon nanotubes. An example of the liquid includes distilled water or alcohol.

The step of forming of the interlayer dielectric can include steps of forming an insulating layer that surrounds the carbon nanotube bundle, and planarizing the insulating layer until the distant end of the carbon nanotube bundle is exposed out of the insulating layer. At this time, the insulating layer can be formed by applying a precursor of a material of the insulating layer and by baking the precursor.

### BRIEF DESCRIPTION OF THE DRAWINGS

A more complete appreciation of the invention and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view of an interlayer wiring structure of a semiconductor device constructed as an embodiment of the present invention;

FIG. 2A is a scanning electron microscope (SEM) image showing carbon nanotubes prior to being densified;

FIG. 2B is a SEM image showing carbon nanotubes forming a bundle after being densified;

FIG. 3 is a schematic drawing illustrating steps of a wet densification method of carbon nanotubes; and

FIGS. 4A through 4E are cross-sectional views illustrating steps of a method of manufacturing an interlayer wiring structure of a semiconductor device constructed as an embodiment of the present invention.

### DETAILED DESCRIPTION OF THE INVENTION

The present invention will now be described more completely with reference to the accompanying drawings in which exemplary embodiments of the invention are shown. First, an interlayer wiring structure of a semiconductor device using carbon nanotubes will be described.

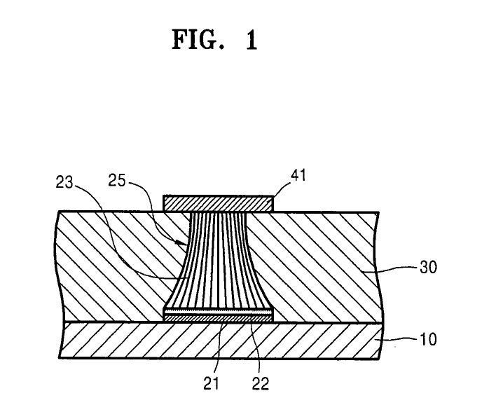

FIG. 1 is a cross-sectional view of an interlayer wiring structure of a semiconductor device constructed as an embodiment of the present invention. Lower electrode (or first electrode) 21 is formed on substrate 10. Catalyst layer 22 is formed on a surface of lower electrode 21 to grow carbon nanotubes from the surface. Carbon nanotube bundle 25 is formed between catalyst layer 22 and upper electrode (or second electrode) 41. Carbon nanotube bundle 25 is an interlayer wire that electrically connects lower electrode (first electrode) 21 to upper electrode (second electrode) 41.

Lower electrode 21, which is made of a conductive material, can be a part of an electrode pattern, or can be a part of a lower layer structure that is to be connected to an upper layer structure by an interlayer wire.

Catalyst layer 22 is formed on a surface of lower electrode 21. A plurality of carbon nanotubes 23 are grown upward from the surface of catalyst layer 22. Carbon nanotube bundle 25 is formed with the plurality of carbon nanotubes 23. The upper end of carbon nanotube bundle 25 contacts upper electrode 41, and the lower end of carbon nanotube bundle 25 contacts lower electrode 21. As shown in FIG. 1, the lower end of each of carbon nanotubes 23 is fixed on catalyst layer 22, and carbon nanotubes 23 move closer to each other as they proceed upward. Therefore, carbon nanotube bundle 25 overall has a cone shape rather than a cylinder shape. A diameter (or a size) of the upper end of carbon nanotube bundle 25 is smaller than a diameter (or a size) of the lower end of carbon nanotube bundle 25. Accordingly, the density of carbon nanotubes 23 at the upper part of carbon nanotube bundle 25 is higher than the density at the lower part of carbon nanotube bundle 25. The density of carbon nanotubes 23 at the lower part of carbon nanotube bundle 25 is determined by the carbon nanotube growing condition such as the grain size of the catalyst metal.

The position and the size (or diameter) of carbon nanotube bundle 25 are determined by the position and the size (or diameter) of catalyst layer 22. The diameter of catalyst layer 22 is normally designed to be bigger than the diameter of the upper end of carbon nanotube bundle 25 by considering an aligning tolerance of upper electrode 41 with respect to catalyst layer 22. For example, the diameter of catalyst layer 22 can be approximately 400 nm to form carbon nanotube bundle 25 having a diameter of 240 nm at the upper end of carbon nanotube bundle 25.

Catalyst layer 22 can be formed of a metal such as nickel (Ni), iron (Fe), cobalt (Co), platinum (Pt), molybdenum (Mo), tungsten (W), yttrium (Y), gold (Au), palladium (Pd), or alloys of these metals.

Carbon nanotube bundle 25 is surrounded by interlayer dielectric 30, and top of carbon nanotube bundle 25 is exposed out of interlayer dielectric 30 to contact upper electrode 41. Upper electrode 41, like lower electrode 21, is made of a conductive material, and can be a part of an electrode pattern, or can be a portion of an upper layer structure that is connected to a lower layer structure by an interlayer wire.

Because a size (or an area) of catalyst layer 22, from which carbon nanotubes 23 grow, can be controlled, the number of carbon nanotubes 23, which is grown from a surface of catalyst layer 22, can be effectively controlled. For example, in order to increase an amount of current flowing through carbon nanotubes 23, the number of carbon nanotubes 23 can be greatly increased by increasing the area of catalyst layer 22.

A method of manufacturing an interlayer wire of a semiconductor device using carbon nanotubes constructed as an embodiment of the present invention will be described. As described above, the upper ends of carbon nanotubes 23 move closer to each other. The process of combining the upper ends of carbon nanotubes 23 is referred to as a densification process. During the densification process, carbon nanotubes 23 are densified, and the upper ends of carbon nanotubes 23 move closer to each other.

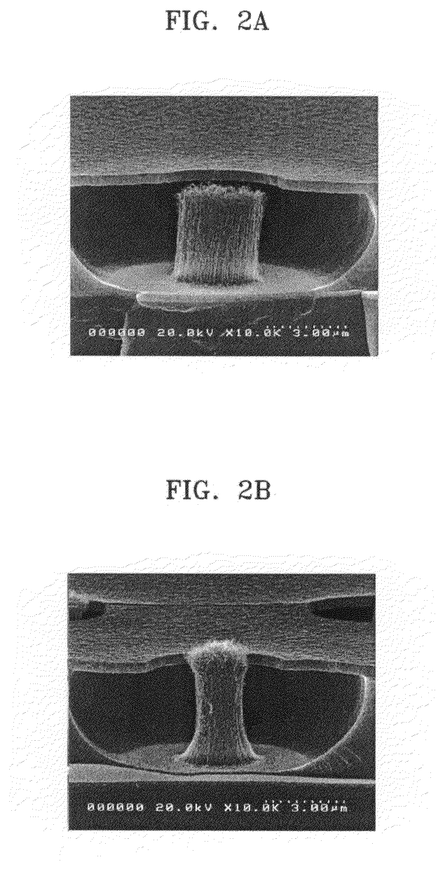

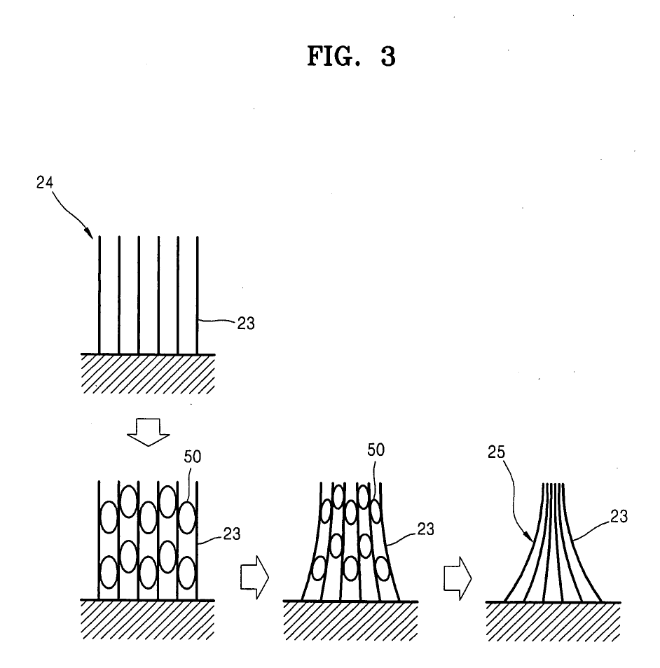

FIG. 2A is a scanning electron microscope (SEM) image showing carbon nanotubes before being densified. Carbon nanotubes are grown substantially straight from a surface of a catalyst layer. FIG. 2B is an SEM image showing carbon nanotubes after being densified. The upper parts of carbon nanotubes are gathered together. As shown in FIG. 2B, the plurality of carbon nanotubes form a bundle, and the bundle has lower density of carbon nanotubes at the lower portion of the bundle, and has higher density of carbon nanotubes at the upper portion of the bundle.

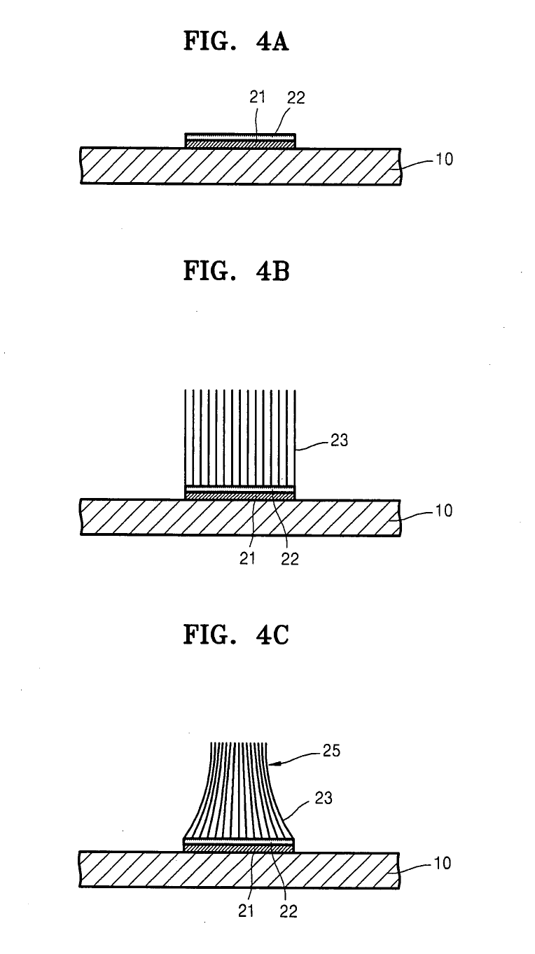

FIG. 3 is a schematic drawing illustrating steps of a wet densification method of carbon nanotubes. First, carbon nanotube group 24 is formed by growing a plurality of carbon nanotubes 23. In carbon nanotube group 24, the density of carbon nanotubes 23 at a root portion (lower portion) of carbon nanotube group 24 is determined by the density of catalyst metal grains, from which carbon nanotubes 23 grow. The density of catalyst metal grains can be determined by gaps between the catalyst metal grains. Next, droplets 50 are distributed between carbon nanotubes 23. Droplets 50 are adsorbed on the surfaces of the plurality of carbon nanotubes 23. As liquid contained in droplets 50 is evaporated, adjacent carbon nanotubes 23 stick together due to increased surface tension, which is induced by droplets 50. Droplets 50 between carbon nanotubes 23 also shrink.

The agglomerate of carbon nanotubes 23 is maintained as it is due to Van der Waals force even after all of droplets 50 are evaporated. As a result, the density of carbon nanotubes 23 increases at the upper part of carbon nanotube group 24, while the density of carbon nanotubes 23 at the lower part of carbon nanotube group 24 is virtually not changed.

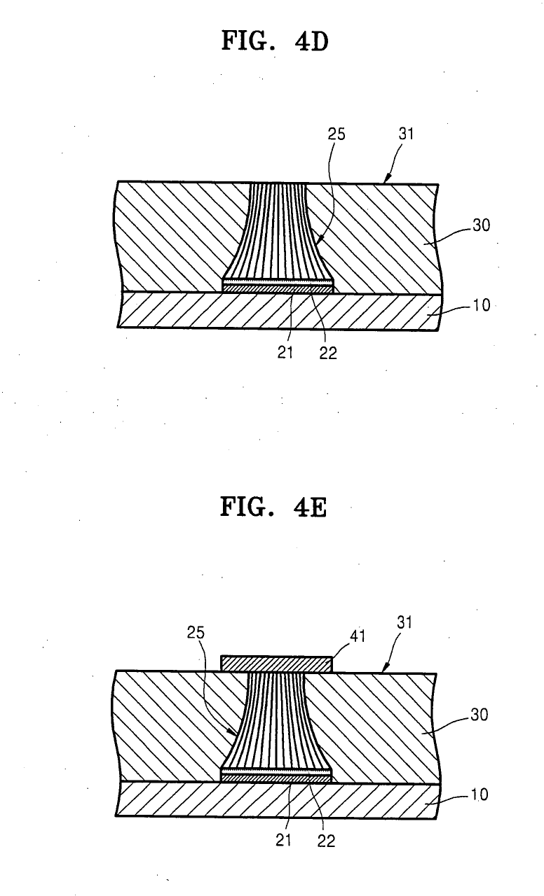

FIGS. 4A through 4E show cross-sectional views illustrating a method of manufacturing an interlayer wiring structure of a semiconductor device constructed as an embodiment of the present invention.

Referring to FIG. 4A, lower electrode 21 is formed on substrate 10, and catalyst layer 22 is formed on lower electrode 21 to assist a formation of carbon nanotubes. Substrate 10 can be a silicon wafer or glass, but the present invention is not limited thereto. For example, substrate 10 can be any layer of a semiconductor device on which carbon nanotubes can be grown. FIG. 4A shows catalyst layer 22 formed on a surface of lower electrode 21, but the present invention is not limited to this structure. In other words, it is not necessary to form catalyst layer 22 on the upper surface of lower electrode 21, but it is necessary to maintain electrical connection between catalyst layer 22 and lower electrode 21. For example, catalyst layer 22 can be formed on a surface of substrate 10 and only a part of catalyst layer 22 can contact lower electrode 21 to maintain electrical connection between carbon nanotubes grown on catalyst layer 22 and lower electrode 22.

Catalyst layer 22 can be formed of a metal such as nickel (Ni), iron (Fe), cobalt (Co), platinum (Pt), molybdenum (Mo), tungsten (W), yttrium (Y), gold (Au), palladium (Pd), or alloys of these metals. Catalyst layer 22 also can be formed by using a magnetron sputtering method or an electron beam deposition method, but the present invention is not limited thereto. For example, the catalyst layer 22 can be formed by coating lower electrode 21 with a powder transition metal catalyst.

Referring to FIG. 4B, a plurality of carbon nanotubes 23 are grown on catalyst layer 22. Carbon nanotubes 23 can be grown by using a thermal chemical vapor deposition (CVD) method, but the present invention is not limited thereto. That is, carbon nanotubes 23 can be grown by any method that can grow a plurality of carbon nanotubes 23 on a surface of catalyst layer 22, such as a plasma enhanced chemical vapor deposition (PECVD) method.

For example, if the PECVD method is used to grow carbon nanotubes 23, the growing process can be performed in a reactor that is maintained at a temperature of 400° C. to 900° C. under an atmosphere of a gas mixture in which carbon monoxide (CO) gas and hydrogen (H₂) gas are mixed in a predetermined ratio. However, the present invention is not limited thereto. That is, carbon nanotubes 23 can be formed by injecting one carbon containing gas such as methane (CH₄), acetylene (C₂H₂), ethylene (C₂H₄), ethane (C₂H₆), carbon monoxide (CO), and carbon dioxide (CO₂) together with at least one of hydrogen (H₂) gas, nitrogen (N₂) gas, oxygen (O₂) gas, water (H₂O), and argon (Ar) gas into the reactor.

Referring to FIG. 4C, carbon nanotubes 23 are soaked in a liquid having high surface tension such as distilled water or alcohol, and the liquid-soaked carbon nanotubes 23 are dried. A plurality of droplets are distributed between carbon nanotubes 23, and carbon nanotubes 23 stick together due to the surface tension induced by the droplets. The method of applying the droplets. between carbon nanotubes 23 is not limited to the method of soaking substrate 10 into a liquid, but various method can be used. For example, carbon nanotubes 23 can be sprayed with a liquid.

In order to make carbon nanotubes 23 stick together, it is preferable that the droplets induce surface tension greater than restoring elastic force of carbon nanotubes 23. The restoring elastic force of carbon nanotubes is referred to as elastic force that makes carbon nanotubes return to their original positions when carbon nanotubes are released from a deformed state. However, even though the surface tension is not strong enough, the goal of the present invention still can be achieved as long as the magnitude of the surface tension is large enough to make the size of the upper end of carbon nanotube bundle 25 be within tolerance of position and size of upper electrode 41.

As described above, the diameter or size of catalyst layer 22 can be designed larger than the diameter or size of the upper end of carbon nanotube bundle 25. The size of catalyst layer is preferably twice or more bigger than the size of the upper end of carbon nanotube bundle 25 in consideration of an aligning tolerance in several optical etching processes which will be performed in the following steps. In the present embodiment, a catalyst layer has been made to have a diameter of approximately 400 nm.

Carbon nanotubes 23 are attracted to each other by Van der Waals force, and once carbon nanotubes 23 stick together, carbon nanotubes 23 remain in the state forming an agglomerate. As a result, the upper parts of carbon nanotubes 23 are densified, and the density of carbon nanotubes 23 at the upper part of carbon nanotube bundle 25 increases, while the roots (lower parts) of carbon nanotubes 23 are strongly attached to catalyst layer 22, and retain the same density as when carbon nanotubes 23 are formed on catalyst layer 22.

Referring to FIG. 4D, interlayer dielectric 30 is formed on an upper surface of substrate 10. Interlayer dielectric 30 can cover and/or surround lower electrode 21, catalyst layer 22, and carbon nanotube bundle 25. Interlayer dielectric 30 can be made of an oxide, for example, a silicon oxide (SiO₂), or an organic precursor of an oxide insulator such as spin-on-glass (SOG). If interlayer dielectric 30 is made of SOG, forming interlayer dielectric 30 using SOG requires three baking processes after a SOG material is applied using a spin coating method. The first process is warming the oxide at 60° C. on a hot plate. The second process is heating the oxide at 100° C. on the hot plate. The third process is heating the oxide at 250° C. on the hot plate. To obtain a desired thickness, the spin coating of the SOG material and the three steps of baking processes can be repeated. Afterward, the resultant product is heated in a furnace at temperature of 430° C. for one hour to obtain interlayer dielectric 30.

Various methods can be further employed to complete interlayer dielectric 30. After an insulating layer covering substrate 10 and carbon nanotube bundle 25 is formed, a top surface of carbon nanotube bundle 25 can be exposed by grinding a portion of the insulating layer formed above carbon nanotube bundle 25. The grinding process can be referred to as a planarizing process or a flattening process. After the planarizing process, interlayer dielectric 30 is completed. Alternatively, the insulating layer can be selectively formed in a manner that the top surface of carbon nanotube bundle 25 is not covered by the insulating material. If interlayer dielectric 30 is formed from an insulator precursor, a pyrolysis or a reduction process can further be conducted. When a CVD method is used to form interlayer dielectric 30, a process of coating surfaces of carbon nanotubes 23 or a surface of nanotube bundle 25 with a metal, by sputtering or a vacuum evaporation method, can be added prior to forming interlayer dielectric 30 in order to prevent carbon nanotubes from being deformed during the CVD process.

The planarizing process can be a chemical mechanical polishing (CMP) process. In the present embodiment, upper surface 31 of interlayer dielectric 30 is flattened by grinding upper surface 31 with an alumina powder until the top surface of carbon nanotube bundle 25 is exposed. The exposed top surface of carbon nanotube bundle 25 has a higher density of carbon nanotubes 23 than the root portions of carbon nanotubes 23 that is fixed on catalyst layer 22.

Referring to FIG. 4E, upper electrode (second electrode) 41 that is connected to the top surface of carbon nanotube bundle 25 is formed on an upper surface of interlayer dielectric 30. Thus, carbon nanotube bundle 25 forms an interlayer wire, such as a contact or an interconnect, that connects lower electrode (first electrode) 21 to upper electrode (second electrode) 41. In this case, although the diameter of the upper part of carbon nanotube bundle 25 that contacts the surface of the upper electrode 41 appears small, electrical resistance of carbon nanotube bundle 25 is very low due to the high density of the carbon nanotubes contained in carbon nanotube bundle 25, and thereby current density can be greatly increased when current flows through carbon nanotube bundle 25. The interlayer wire that is made of carbon nanotubes can be formed to have a diameter of a few to a few tens of nanometers. Therefore, the interlayer wire can be applied to form a minute via hole having a diameter of a few to a few tens of nanometers. Accordingly, an extremely high integration of a semiconductor device can be achieved. Upper electrode 41 can have an electrode pattern for wiring in the semiconductor device or can be a portion of a structure disposed on an upper layer of the semiconductor device.

An interlayer wire of a semiconductor device of the present invention can reduce electrical resistance and increase current density using highly densified carbon nanotubes. A method of manufacturing an interlayer wire of the present invention provides a method of effectively manufacturing an interlayer wire of a semiconductor device that includes a highly densified carbon nanotube bundle.

Also, the method of manufacturing an interlayer wire of the present invention can be applied to manufacture a via hole having a few tens to a few hundreds of nanometers. Therefore, the present invention provides an interlayer wire of a semiconductor device that can achieve an extremely high integration of a semiconductor device, and a method of manufacturing the interlayer wire.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An interlayer wiring structure of a semiconductor device comprising:
a first electrode;
a catalyst layer for growing carbon nanotubes, the catalyst layer electrically connected to the first electrode;
a second electrode spaced apart from the catalyst layer;
a carbon nanotube bundle formed between the catalyst layer and the second electrode; the carbon nanotube bundle electrically connecting the second electrode to the catalyst layer; the carbon nanotube bundle including a plurality of carbon nanotubes that are grown from the catalyst layer; a portion of the carbon nanotube bundle close to the second electrode having higher density of carbon nanotubes than another portion of the carbon nanotube bundle close to the first electrode; and
an interlayer dielectric surrounding the carbon nanotube bundle.

2. The interlayer wiring structure of claim 1, comprised of the catalyst layer including a material selected from the group consisting of nickel (Ni), iron (Fe), cobalt (Co), platinum (Pt), molybdenum (Mo), tungsten (W), yttrium (Y), gold (Au), palladium (Pd), and alloys thereof.

3. A method of manufacturing an interlayer wire of a semiconductor device, the method comprising:
preparing a first electrode;
forming a catalyst layer for growing carbon nanotubes, the catalyst layer being electrically connected to the first electrode;
growing a plurality of carbon nanotubes from the catalyst layer;
forming a carbon nanotube bundle that includes the plurality of carbon nanotubes, a portion of the carbon nanotube bundle close to the first electrode having lower density of carbon nanotubes than another portion of the carbon nanotube bundle distant to the first electrode;
forming an interlayer dielectric that surrounds the carbon nanotube bundle, a distant end of the carbon nanotube bundle distant to the first electrode being exposed out of the interlayer dielectric; and
forming a second electrode connected to the distant end of the carbon nanotube bundle, the second electrode being electrically connected to the first electrode through the carbon nanotube bundle and the catalyst layer.

4. The method of claim 3, comprised of the catalyst layer including a material selected from the group consisting of nickel (Ni), iron (Fe), cobalt (Co), platinum (Pt), molybdenum (Mo), tungsten (W), yttrium (Y), gold (Au), palladium (Pd), and alloys thereof.

5. The method of claim 3, wherein the catalyst layer is formed by a magnetron sputtering method or by an electron beam deposition method.

6. The method of claim 3, comprised of the step of forming the interlayer dielectric comprising:
forming an insulating layer that surrounds the carbon nanotube bundle; and
planarizing the insulating layer until the distant end of the carbon nanotube bundle is exposed out of the insulating layer.

7. The method of claim 6, comprised of the step of forming the insulating layer including a step of applying a precursor of a material of the insulating layer.

8. The method of claim 3, further comprising a step of coating a surface of the carbon nanotube bundle with a metal prior to the step of forming the interlayer dielectric.

9. The method of claim 3, comprised of the step of forming the carbon nanotube bundle including:
distributing droplets between the plurality of the carbon nanotubes; and
evaporating the droplets.

10. The method of claim 9, comprised of the step of distributing droplets including a step of soaking the carbon nanotubes in a liquid.

11. The method of claim 9, comprised of the step of distributing droplets including a step of spraying the carbon nanotubes with a liquid.

12. The method of claim 9, comprised of the droplets inducing surface tension between the carbon nanotubes, the surface tension being greater than restoring elastic force of carbon nanotubes.

13. The method of claim 12, comprised of the droplets including distilled water or alcohol.

14. An interlayer wiring structure of a semiconductor device comprising:
a lower electrode;
a catalyst layer formed on a surface of the lower electrode and growing carbon nanotubes;
an upper electrode spaced apart from the catalyst layer;
a carbon nanotube bundle formed between the catalyst layer and the upper electrode, a lower end of the carbon nanotube bundle contacting the catalyst layer, an upper end of the carbon nanotube bundle contacting the upper electrode, the carbon nanotube bundle including a plurality of carbon nanotubes that are grown from the catalyst layer, the upper end of the carbon nanotube bundle having higher density of carbon nanotubes than the lower end of the carbon nanotube bundle; and
an interlayer dielectric formed in a space between the catalyst layer and the upper electrode, the interlayer dielectric surrounding the carbon nanotube bundle.

15. The interlayer wiring structure of claim 14, comprised of the catalyst layer including a material selected from the group consisting of nickel (Ni), iron (Fe), cobalt (Co), platinum (Pt), molybdenum (Mo), tungsten (W), yttrium (Y), gold (Au), palladium (Pd), and alloys thereof.
